(19) United States
(12) Patent Application Publication
(10) Pub. No.: US 2010/0102375 A1
(43) Pub. Date: Apr. 29, 2010

(54) SEMICONDUCTOR DEVICE AND MANUFACTURING METHOD THEREOF

(75) Inventor: Takashi AOI, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/607,600

(22) Filed: Oct. 28, 2009

(30) Foreign Application Priority Data
Oct. 28, 2008 (JP) 2008-277444

(51) Int. Cl. H01L 29/788; H01L 21/336

(52) U.S. Cl. 257/316; 438/261; 257/E29.3; 257/E21.422

(57) ABSTRACT

This semiconductor device comprises a semiconductor substrate with a first impurity type; a plurality of active areas formed in the semiconductor substrate; an element isolation trench including a first trench part and a second trench part surrounding the plurality of active areas, the first trench part being extended from a surface of the semiconductor substrate to a depth direction, the second trench part being extended from the center of a bottom surface of the first trench part to the depth direction with a narrower width than the width of the first trench part in a width direction; an element isolation insulator film filled in the element isolation trench; a gate electrode formed on the plurality of active areas via a gate insulator film; a plurality of diffusion layers with a second impurity type formed in a surface of the plurality of active areas, the plurality of diffusion layers being located on each side of the element isolation trench and separated each other on each side of the gate electrode; and a channel stop region extended from the bottom surface of the second trench part to the depth direction in a predetermined depth with the first impurity type, the channel stop region having a higher impurity concentration than the impurity concentration of the semiconductor substrate.

### CROSS REFERENCE TO RELATED APPLICATIONS

This application is based on and claims the benefit of priority from prior Japanese Patent Application No. 2008-277444, filed on Oct. 28, 2008, the entire contents of which are incorporated herein by reference.

### BACKGROUND OF THE INVENTION

1. Field of the Invention

The present invention relates to a semiconductor device and its fabrication process especially the device with high voltage transistors operated in a high voltage.

2. Description of the Related Art

In non-volatile semiconductor memory devices, such as flush memories, a high voltage of 20-30 V is necessary when data is programmed to memory cells. A plurality of high voltage transistors are employed, for example, in a word line driving circuit used for programming of data. The plurality of high voltage transistors are isolated each other by STI (Shallow Trench Isolation) including a shallow trench and an element isolation insulator film. However, a leakage current at a semiconductor substrate under the STI exists because of the high operation voltage. To prevent the leakage current, a region with the same impurity type as the semiconductor substrate and has a higher impurity concentration than the semiconductor substrate is formed under the shallow trench. The region is called a channel stop region hereinafter.

An impurity profile of the channel stop region is affected by a thickness variation of the element isolation insulator film when the channel stop region is formed by an ion implantation through the element isolation insulator film. To avoid this problem, ion implantation for the channel stop region is carried out after forming the shallow trench, using a photo resist pattern with an opening at the center of the shallow trench as a mask. (Ref. Japanese Patent Laid Open P2002-141408 page 6, FIG. 4)

However, with the method explained above, a residual photo resist may exist in the shallow trench due to an insufficient exposure of the photo resist at the bottom of the shallow trench caused by a large step between the surface of the semiconductor substrate and the bottom of the shallow trench. The residual photo resist makes the ion implantation process unstable and a controllability of the impurity profile of the channel stop region is likely to become worse.

### SUMMARY OF THE INVENTION

One aspect of this invention is to provide a semiconductor device comprises: a semiconductor substrate with a first impurity type; a plurality of active areas formed in the semiconductor substrate; an element isolation trench including a first trench part and a second trench part surrounding the plurality of active areas, the first trench part being extended from a surface of the semiconductor substrate to a depth direction, the second trench part being extended from the center of a bottom surface of the first trench part to the depth direction with a narrower width than the width of the first trench part in a width direction; an element isolation insulator film filled in the element isolation trench; a gate electrode formed on the plurality of active areas via a gate insulator film; a plurality of diffusion layers with a second impurity type formed in a surface of the plurality of active areas, the plurality of diffusion layers being located on each side of the element isolation trench and separated each other on each side of the gate electrode; and a channel stop region extended from the bottom surface of the second trench part to the depth direction in a predetermined depth with the first impurity type, the channel stop region having a higher impurity concentration than the impurity concentration of the semiconductor substrate.

Another aspect of this invention is to provide a method of manufacturing a semiconductor memory device comprises: forming a first trench part in a semiconductor substrate with a first impurity type; filling the first trench part with a first element isolation insulator film; planerizing a surface of the first element isolation insulator film; forming a photo resist pattern on the surface of the first element isolation insulator film, the photo resist pattern having an opening on the center of the first element isolation insulator film; etching the first element isolation insulator film to expose the semiconductor substrate at the bottom of the first trench part, using the photo resist pattern as a mask; etching the exposed semiconductor substrate to form a second trench part, the second trench part having a narrower width than the width of the first trench part, and being extended from the bottom surface of the first trench part to a depth direction; implanting ions of the first impurity type element to form a channel stop region using the photo resist pattern as a mask, the channel stop region being extended from the bottom of the second trench part to the depth direction in a predetermined depth with the first impurity type and having a higher impurity concentration than the semiconductor substrate; filling a second element isolation insulator film in the second trench part; forming a gate electrode on the surface of the semiconductor substrate via a gate insulator film; and forming diffusion layers having a second impurity type opposite of the first impurity type in the surface of the semiconductor substrate, the diffusion layers being located on each side of the first trench part, and being separated each other on each side of the gate electrode.

### BRIEF DESCRIPTION OF THE DRAWINGS

FIG. 1 is a block diagram of a NAND flash memory device according to an embodiment of the present invention.

FIG. 2 is a plan diagram of a high voltage transistor of a NAND flash memory device according to the embodiment of the present invention.

FIGS. 3A and 3B are cross-sectional diagrams of a NAND flash memory device according to the embodiment of the present invention taken along the lines A-A and B-B shown in FIG. 2, respectively.

FIGS. 4A and 4B are cross-sectional diagrams showing the fabrication method of a NAND flash memory device according to the embodiment of the present invention.

FIGS. 5A and 5B are cross-sectional diagrams showing the fabrication method of a NAND flash memory device subsequent to FIGS. 4A and 4B.

FIGS. 6A and 6B are cross-sectional diagrams showing the fabrication method of a NAND flash memory device subsequent to FIGS. 5A and 5B.

FIGS. 7A and 7B are cross-sectional diagrams showing the fabrication method of a NAND flash memory device subsequent to FIGS. 6A and 6B.

FIGS. 8A and 8B are cross-sectional diagrams showing the fabrication method of a NAND flash memory device subsequent to FIGS. 7A and 7B.

FIGS. 9A and 9B are cross-sectional diagrams showing the fabrication method of a NAND flash memory device subsequent to FIGS. 8A and 8B.

FIGS. 10A and 10B are cross-sectional diagrams showing the fabrication method of a NAND flash memory device subsequent to FIGS. 10A and 10B.

FIGS. 11A and 11B are cross-sectional diagrams showing the fabrication method of a NAND flash memory device subsequent to FIGS. 11A and 11B.

FIGS. 12A, 12B and 12C are cross-sectional diagrams showing the fabrication method of a NAND flash memory device according to the embodiment of the present invention. FIG. 12A is a cross-sectional diagram showing the ion implantation process to the channel stop region with a nominal depth trench.

FIG. 12B is a cross-sectional diagram showing the ion implantation process to the channel stop region with a shallower trench than the nominal depth. FIG. 12C is a cross-sectional diagram showing the ion implantation process to the channel stop region with a deeper trench than the nominal depth.

FIGS. 13A and 13B are cross-sectional diagrams of a NAND flash memory device according to a first modified embodiment of the present invention taken along the lines A-A and B-B shown in FIG. 2, respectively.

FIG. 14 is a plan diagram of a high voltage transistor of a NAND flash memory device according to a second modified embodiment of the present invention.

FIGS. 15A and 15B are cross-sectional diagrams of a NAND flash memory device according to the second modified embodiment of the present invention taken along the lines A-A and B-B shown in FIG. 14, respectively.

### DETAILED DESCRIPTION OF THE EMBODIMENTS

As a semiconductor memory device according to an embodiment of the invention, a NAND flash memory device is described with reference to the accompanying drawings. In the drawings to be referred to in the following description, the same or similar reference numerals designate the same or similar parts. The drawings are schematic, and the ratio between thickness and the planner dimension of each part, and the ratio among the thickness of layers differ from actual ones, for example.

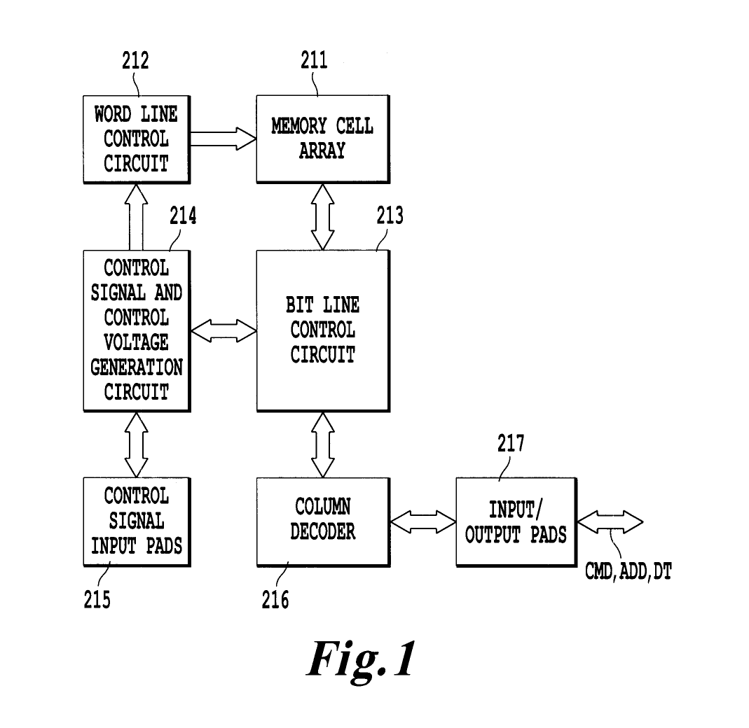

FIG. 1 is a block diagram of a NAND flash memory device according to the embodiment of the invention. As shown in FIG. 1, the NAND flash memory device includes memory cell arrays 211, a word line control circuit 212, a bit line control circuit 213, a control signal and control voltage generation circuit 214, control signal input pads 215, a column decoder 216, and data input/output pads 217.

The memory cell array 211 includes a plurality of blocks. The memory cell array 211 is coupled to the word line control circuit 212 and the bit line control circuit 213, which controls word lines, and the bit lines of memory cells in the memory cell array, respectively.

The word line control circuit 212 selects a word line in the memory cell array 211 to apply reading, programming, or erasing voltage to the selected word line.

The bit line control circuit 213 reads data of a memory cell in the memory cell arrays 211 via a bit line. It also programs to a memory cell with applying a program control voltage to a corresponding bit line. The column decoder 216 and the control signal and control voltage generation circuit 214 are connected to the bit line control circuit 213.

A data latch circuit (not shown) is included in the bit line control circuit 213, and the data latch circuit is selected by the column decoder 216. Memory cell data in the data latch circuit is output from the data input/output pads 217 via the column decoder 216. The data input/output pads 217 are coupled to host devices outside of the NAND flash memory device.

The control signal and control voltage generation circuit 214 controls the memory cell array 211, the word line control circuit 212, and the bit line control circuit 213. The control signal and control voltage generation circuit 214 is electrically connected to the control signal input pads 215, and controlled by a control signal ALE (Address Latch Enable) input from a host device via the control signal input pads 215, for example.

A programming circuit and a reading circuit include the word line control circuit 212, the bit line control circuit 213, the column decoder 216, and the control signal and control voltage generation circuit 214. High voltage transistors are used, for example, in a word line driver circuit of the word line control circuit 212 because high voltage is necessary during programming data to memory cells.

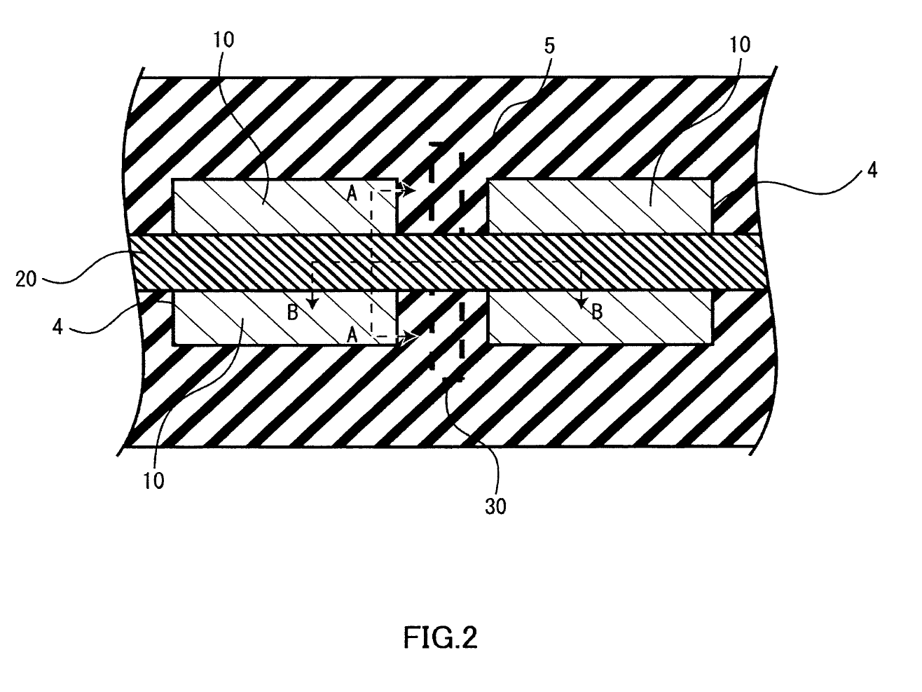

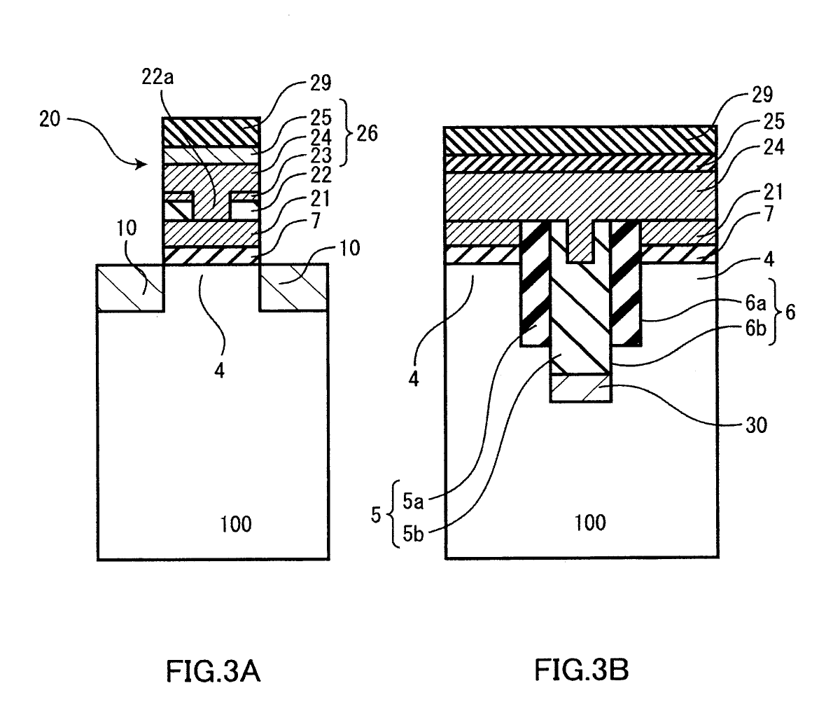

Structure of high voltage transistors and their peripheral area of a NAND flash memory device according to the embodiment of the present invention will be explained in reference with FIG. 2 and FIG. 3.

FIG. 2 is a plan view of the high voltage transistors and their peripheral area. As shown in FIG. 2, an element isolation insulation film 5 is formed to surround at least two neighboring active areas 4 on each of which the high voltage transistor is formed. A gate electrode 20 is formed on each active area 4. A channel stop region 30 is formed in a semiconductor substrate (100 in FIGS. 3A and 3B) between the two active areas 4, under the element isolation insulation film 5. Diffusion layers (source/drain) 10 of the high voltage transistors are formed in a surface of the active areas 4 at each sides of the gate electrode 20.

FIGS. 3A and 3B are cross sectional views of FIG. 2, taken along A-A and B-B of FIG. 2, respectively.

As shown in FIG. 3A, a gate insulator film 7 is formed on the active areas 4 divided by the element isolation region. On the gate insulator film 7, the gate electrode 20 of the high voltage transistor is formed. The gate electrode 20 includes a lower gate electrode made of a poly silicon layer 21 formed on the gate insulation film 7, a inter poly insulator film 22 made of ONO (Oxide-Nitride-Oxide) film, Al2O3, HfO or a laminated film of these materials formed on the lower gate electrode, and an upper gate electrode 26 made of poly silicon layers 23, 24 and a metal silicide layer 25, such as WSi, CoSi, or NiSi. The poly silicon layers 23 and 24 of the upper electrode 26 are electrically connected with the lower electrode 21 via a slit 22a formed in the inter poly insulator film 22. A cap silicon nitride layer 29 used for an etching mask is formed on the upper gate electrode 26

As shown in FIG. 3B, the two active areas 4 are separated by an element isolation trench 6. The element isolation trench includes a first trench part 6a and a second trench part 6b. The first trench part 6a is extended from the surface of the semiconductor substrate 100 to a direction of the back of the semiconductor substrate 100 (hereinafter called the depth direction) with a predetermined depth. The second trench part 6b is extended from the center of the bottom surface of the first trench part 6a to the depth direction with a predetermined depth. The depth of the second trench part 6b measured from the surface of the semiconductor substrate 100 is larger than the depth of the first trench part 6a measured from the surface of the semiconductor substrate 100. The width of the second trench part 6b measured in the B-B line direction in FIG. 2 (hereinafter called the width direction) is smaller than that of the first trench part 6b.

A first element isolation insulator film 5a is filled in the first trench part 6a except the area where the second trench part 6b is formed. The upper surface of the first element isolation insulator film 5a is projected from the surface of the semiconductor substrate 100 and is located in the same height as the top surface of the lower electrode 21. A second element isolation insulation film 5b is filled in the second trench part 6b. The second element isolator film 5b is the same materials as the inter poly insulator film 22 shown in FIG. 3A, and has a divot on its top surface.

A channel stop region 30 is located in the semiconductor substrate 100 under the second trench part 6b, and is substantially the same size as the second trench part 6b both in the width direction and the direction orthogonal to the width direction. The channel stop region 30 has a predetermined depth with the same impurity type as the semiconductor substrate 100 and has a higher concentration than the semiconductor substrate 100. The channel stop region 30 is contacted directly to the bottom of the second trench part 6b.

Though two active areas are drawn in FIGS. 2 and 3, the number of the active area is not limited to two, can be more than two.

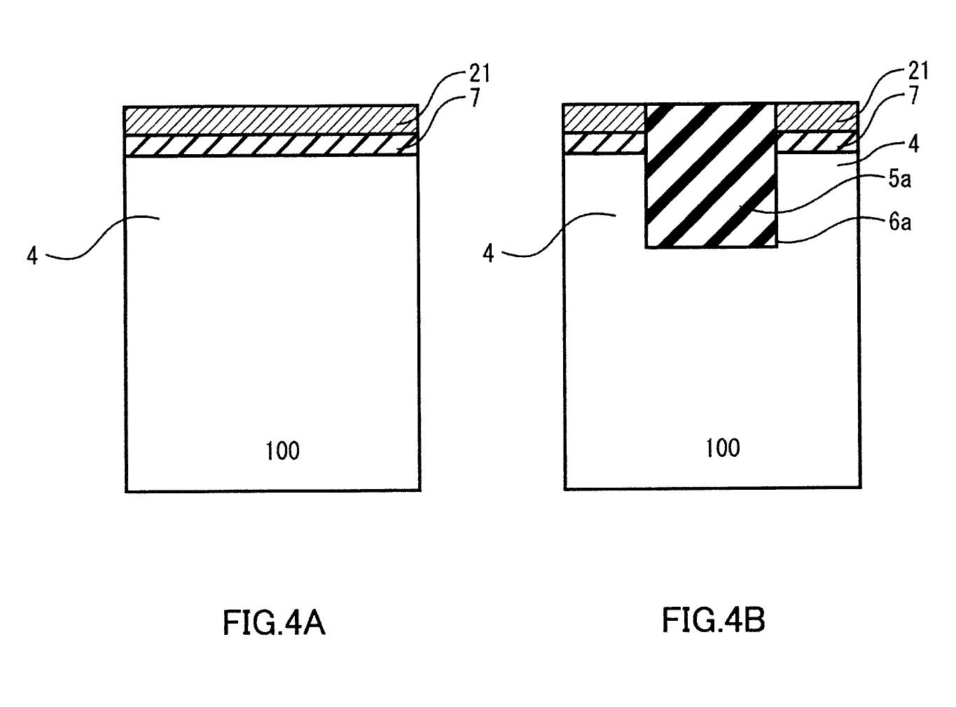

The manufacturing method of the semiconductor device according to the embodiment will now be described with reference to FIGS. 4 to 11. FIGS. 4A to 11A and FIGS. 4B to 11B represent cross sectional views along the line A-A and the line B-B in FIG. 2, respectively.

In the first step, a sacrificial silicon dioxide (not shown) is formed on a p-type semiconductor substrate 100. Photo resist patterns (not shown) are formed on the sacrificial silicon dioxide with a photo lithography process. Then, boron (B) is implanted with masks of the photo resist patterns.

In the next step, the photo resist patterns and the sacrificial silicon dioxide are stripped and a gate insulator film 7 is formed on the semiconductor substrate 100. On the gate insulator film 7, a poly silicon layer 21 is formed and a pad silicon nitride layer (not shown) is formed on the poly silicon layer 21. Then, a photo resist (not shown) is applied on the pad silicon nitride layer. The photo resist is patterned into shapes of active areas with the photo lithography process. The pad silicon nitride layer, the poly silicon layer 21, the gate insulator film 7 and the semiconductor substrate 100 are etched using the photo resist patterns as masks, and the first trench part 6b is formed in the semiconductor substrate 100.

A first element isolation insulator film 5a such as silicon dioxide is deposited in the first trench 6a with a HDP (High Density Plasma) method, and the upper part of the first element isolation insulator film 5a is planerized by a CMP (Chemical Mechanical Polishing) method with the pad silicon nitride layer used as a stopper. The pad silicon nitride layer is stripped by a wet process with Phosphorous acid after the first element isolation insulator film 5a is etched to the same height as the poly silicon layer 21 by a RIE (Reactive Ion Etching) method. The first element isolation insulator film 5a is formed in the first trench part 6a as shown in FIG. 4.

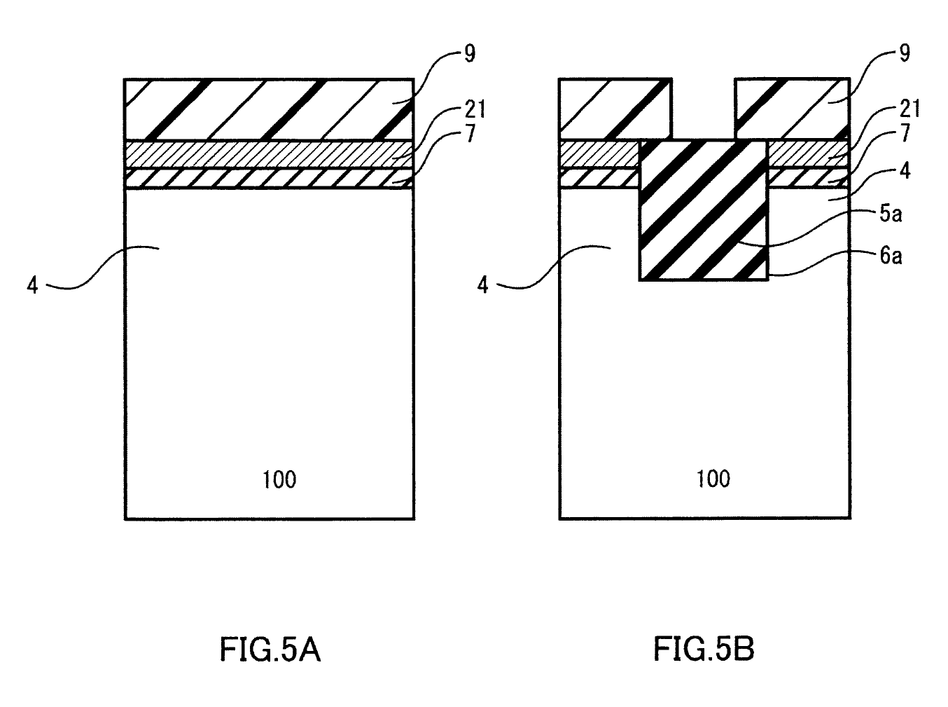

As shown in FIG. 5, a photo resist is applied on the first element isolation insulator film 5a and the poly silicon film 21. Then, a photo resist pattern 9 with an opening on the center of the first element isolation region 5a is formed by a photo lithography method to make a channel stop region.

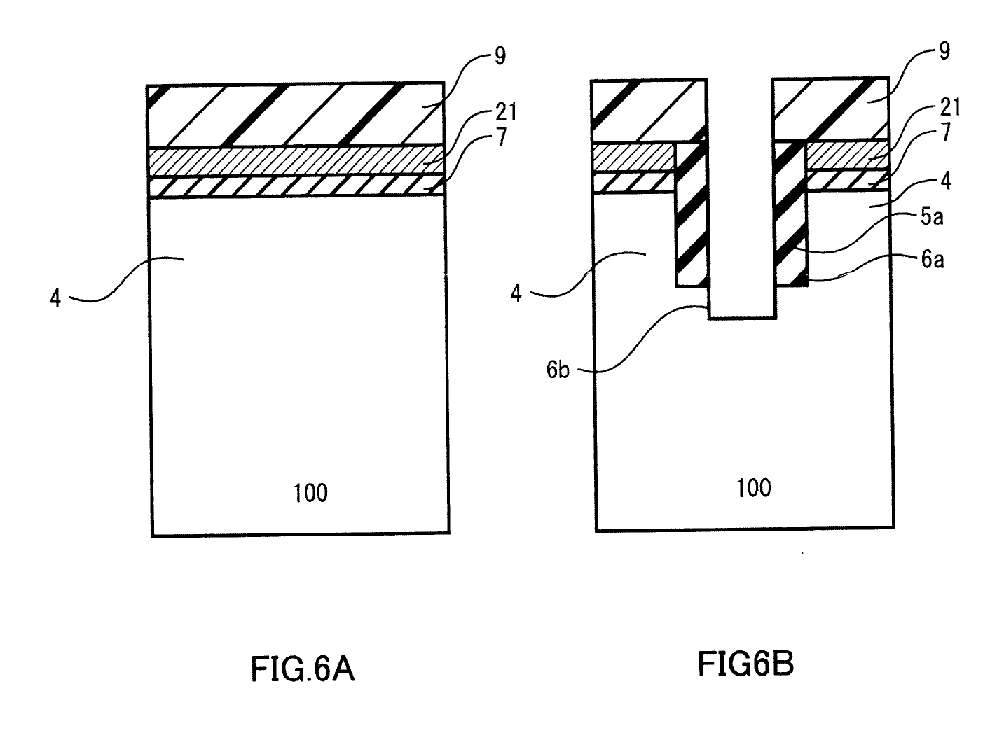

As shown in FIG. 6, the center part of the first element isolation film 5a is etched by the RIE method with the mask of the photo resist pattern 9, and the second trench part 6b is formed in the semiconductor substrate 100. In this etching process, about 10% of over etching to the depth of the first trench part 6a is performed because of the consideration for the depth variation of the first trench part 6a within a wafer. During this over etching, the semiconductor substrate 100 located under the first trench part 6a is etched, and the second trench part 6b is formed. The width of the second trench part 6b measured in the width direction is narrower than the width of the first trench part 6a. And the bottom of the second trench part 6b is located at a lower position than the bottom of the first trench part 6a.

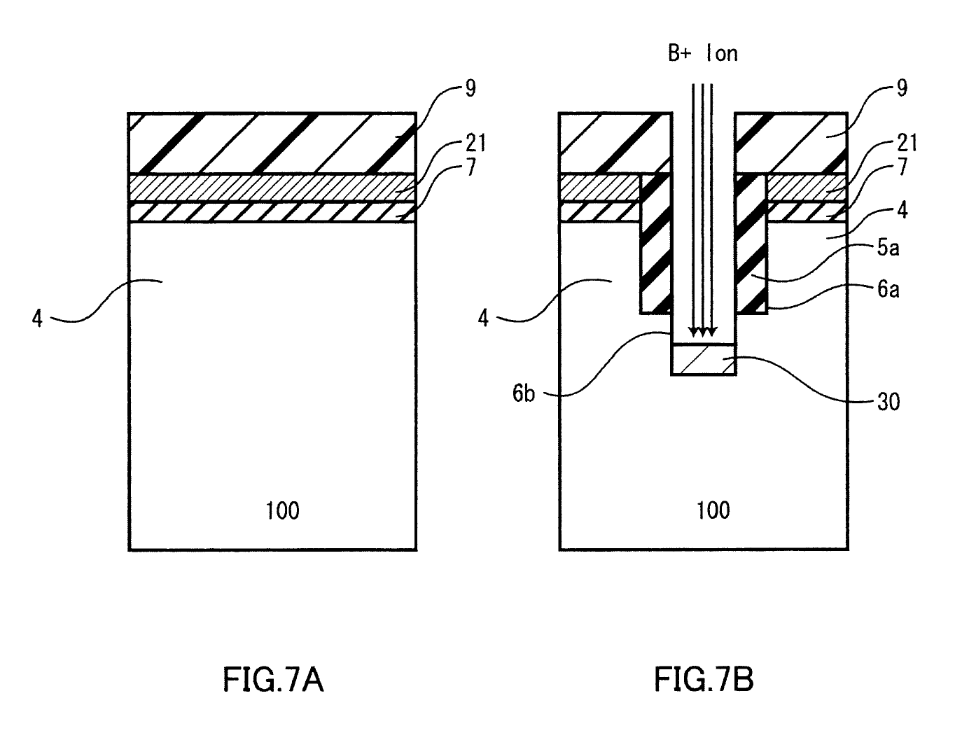

As shown in FIG. 7, boron (B) is implanted into the semiconductor substrate 100 under the second trench part 6b with the photo resist pattern 9 used as a mask. This ion implantation process can be performed with a low acceleration voltage of 10-20 keV because it is not through the first element isolation insulator film 5a. Furthermore, as the ion implantation process is not affected by the depth variation of the first trench part 6a within the wafer, the channel stop region 30 can be formed with a well controlled profile in the semiconductor substrate 100 directly contacted to the bottom of the second trench part 6b.

The etching process of the first element isolation insulator film 5a and the stripping process of the pad silicon nitride layer can be performed after the formation of the second trench part 6b and the ion implantation.

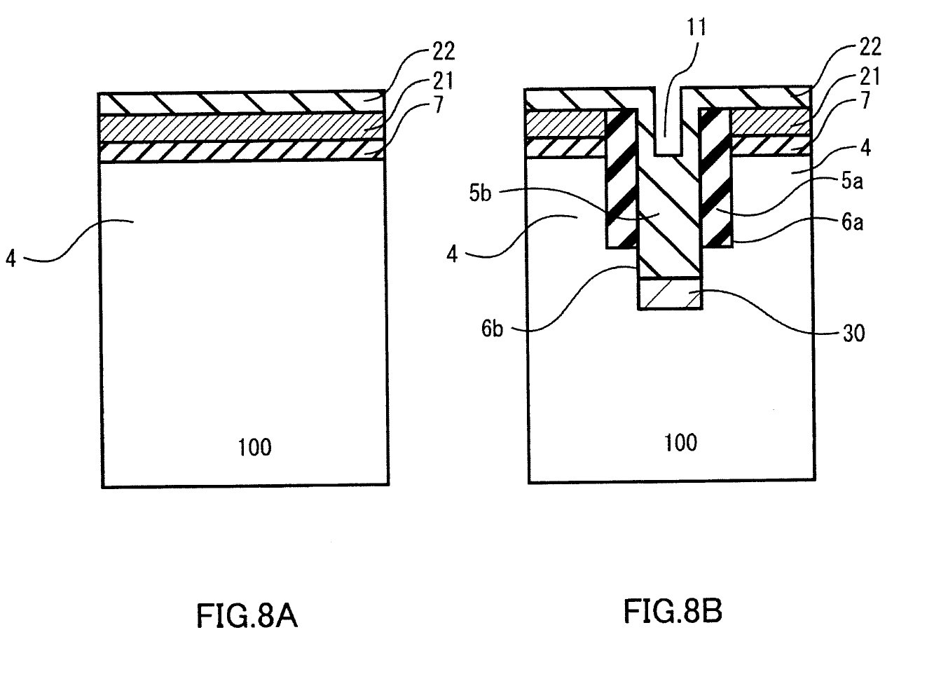

In the next step, as shown in FIG. 8, the photo resist pattern 9 is stripped and the inter poly insulator film 22 comprising ONO film or metal oxides is formed in the second trench part 6b and on the poly silicon layer 21. A divot 11 is formed at the same time because the second trench 6b part is not filled completely with the inter gate insulator film 22.

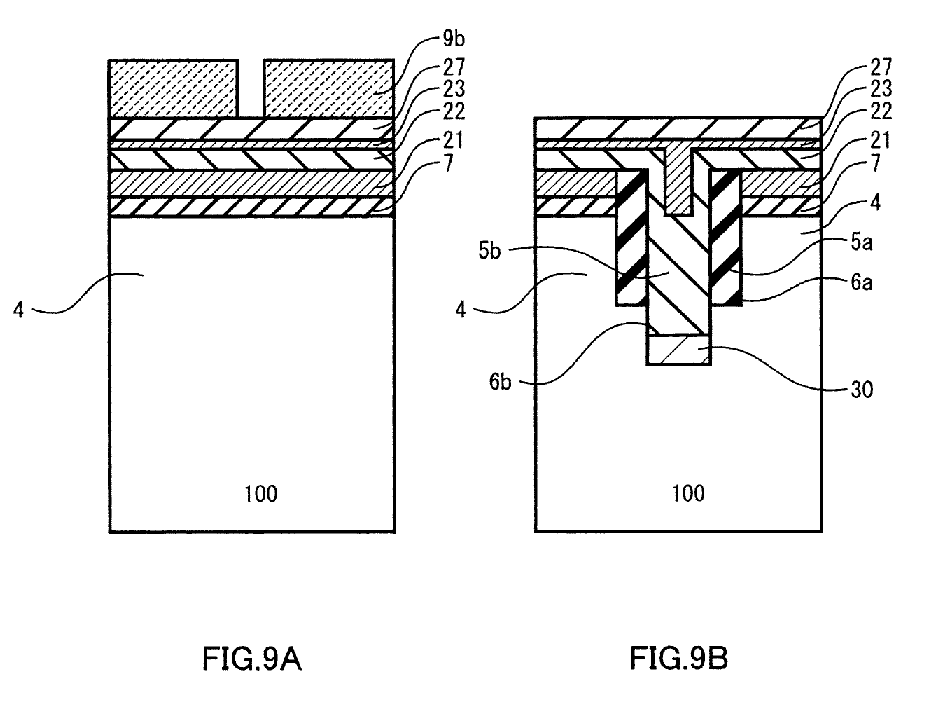

As shown in FIG. 9, a poly silicon layer 23, which is a part of upper gate electrodes, and a mask BSG (Boron Silicate Glass) layer 27, which is used as a mask for the inter poly insulator film 22 etching are formed on the inter poly insulator film 22. Then, a photo resist is applied on the mask BSG layer 27, and a photo resist pattern 9b with an opening to form a slit 22a in the inter poly insulator film 22 is formed by a photo lithography method. The slits 22a are used to electrically connect lower gate electrodes made of the poly silicon layer 21 and the poly silicon layers 23 and 24, which are parts of the upper gate electrodes 26. The slits 22a are located on gate electrodes of peripheral transistors including high voltage transistors and select gate transistors in memory cell arrays. The poly silicon layer 23 is filled in the divot 11 on the inter gate film 22.

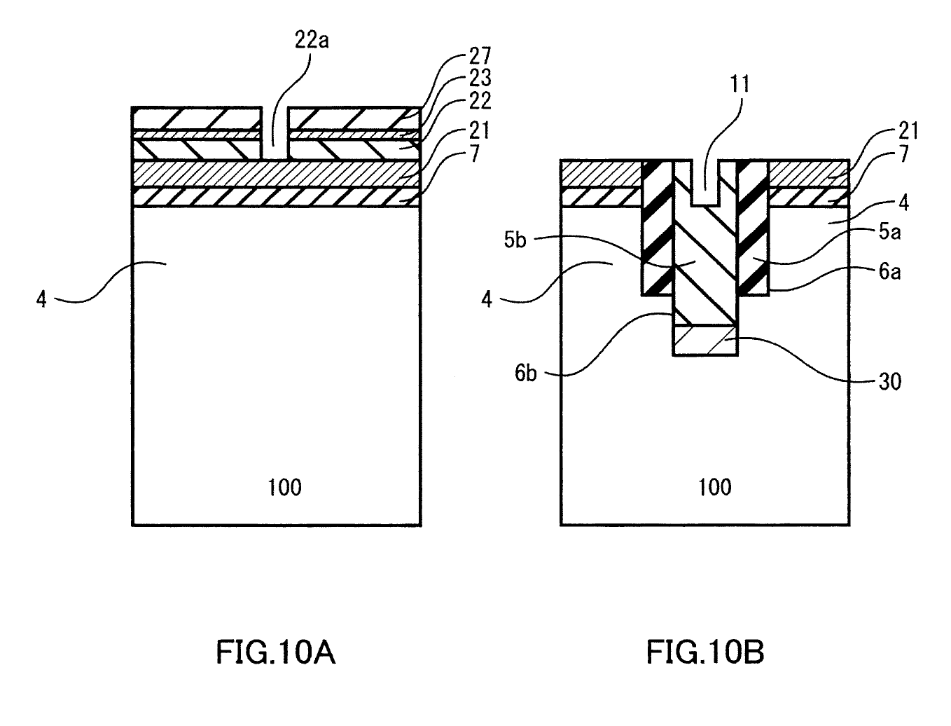

As shown in FIG. 10, the mask BSG layer 27 is etched by the RIE method with the photo resist patterns 9b used as masks. After the photo resist patterns 9b are stripped, the poly silicon layer 23 and the inter gate insulator film 22 are etched with the BSG layer 27 used as a mask. Then, the slit 22a is formed in the inter gate insulator film 22. During the etching of the poly silicon layer 23, the poly silicon layer 23 in the second trench part 6b is removed simultaneously, and the divot 11 appears again on the second element isolation insulator film 5b.

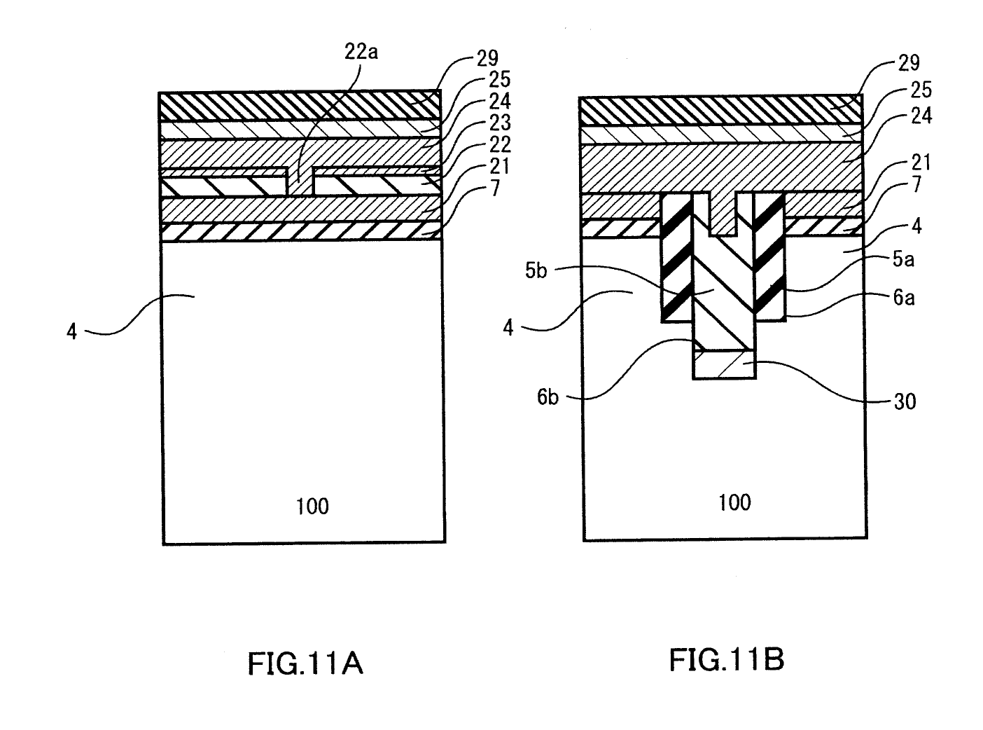

As shown in FIG. 11, the mask BSG layer 27 is removed by Fluorine acid (HF), and a poly silicon layer 24, which is a part of the upper gate electrodes 26, is formed on the poly silicon layer 23. A metal silicide layer 25 such as WSi, CoSi, NiSi and a cap silicon nitride layer 29 are formed on the poly silicon layer 24. The poly silicon layer 24 is filled in the divot 11 on the second element isolation insulator film 5b in this process.

After a photo resist (not shown) is applied on the cap silicon nitride 29, photo resist patterns of the gate electrodes are formed by a photo lithography process. Using the photo resist patterns as masks, the cap silicon nitride 29 is etched by the RIE method. After the photo resist patterns are stripped, the metal silicide layer 25, the poly silicon layer 24, the inter gate film 22, the poly silicon layer 21 and the gate insulator film 7 are etched with the silicon nitride 29 used as a mask and the gate electrodes are formed. Diffusion layers 10 used for source/drain of high voltage transistors is formed by an ion implantation process with the gate electrodes 20 as a mask for the implantation. Thus, high voltage transistors shown in FIG. 2 and FIG. 3 are fabricated. After the formation of the high voltage transistors, an inter layer dielectric is deposited, and planerinzed by the CMP method. Then, bit line contacts are formed in the inter layer dielectric, and bit lines are formed on the inter layer dielectric.

A metal silicide layer such as CoSi or NiSi can also be formed on the upper gate electrode with an alternative process as following. The cap nitride layer 29 is formed on the poly silicon layer 24, and the gate electrodes are formed with the photo lithography process and the RIE method. After the inter layer dielectric is deposited and planerinzed, the cap nitride 29 is stripped and the poly silicon layer 24 is exposed. Then, a metal layer such as Co or Ni is deposited on the poly silicon layer 24. A heat treatment is performed and CoSi or NiSi is formed on the poly silicon layer 24.

The poly silicon layers 21, 23 and 24 can be replaced by other materials like amorphous silicon.

According to the embodiment of the present invention, the first element isolation insulator film 5a is formed in the first trench part 6a, and the upper part of the first element isolation insulator film 5a is planerized. A photo resist pattern with an opening on the center of the first element isolation insulator film 5a′s surface is formed by the photo lithography process. The first element isolation insulator film 5a and the semiconductor substrate 100 are etched with the photo resist pattern used as a mask to form the second trench part 6b. Then, the ion implantation into the second trench 6b to form the channel stop region 30 is performed with the photo resist used as a mask. In the embodiment of the present invention, a residual resist does not exist at the ion implantation process because the photo resist pattern used for the mask of ion implantation is formed on the flat surface of the first element isolation insulator film 5a by a photo lithography process. The controllability of the channel profile of the channel stop region 30 becomes better because there is no effect from the residual photo resist during the ion implantation process.

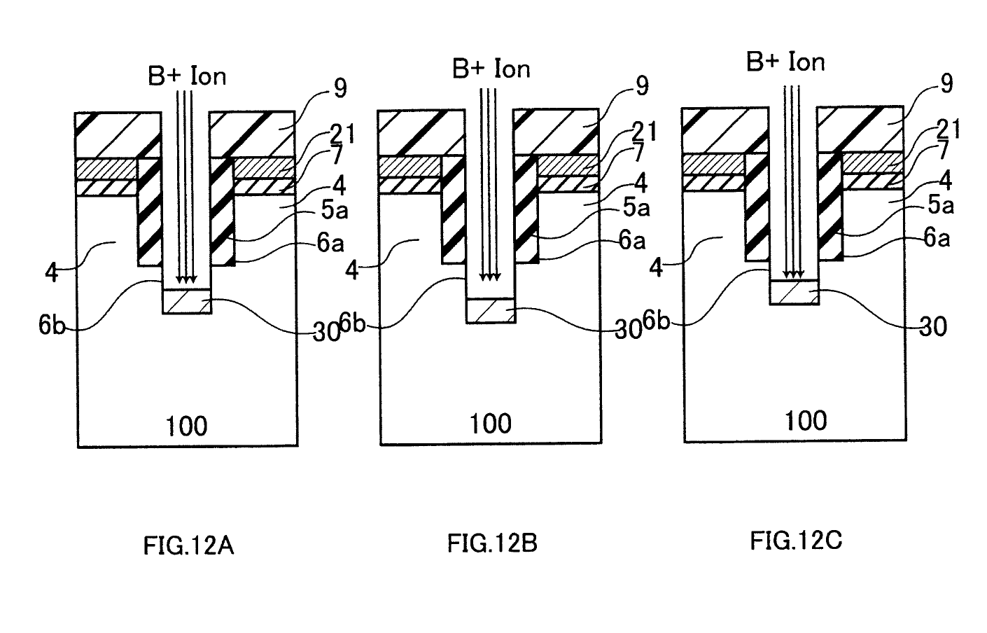

Furthermore, the second trench part 6b is formed in the semiconductor substrate 100 by the over etching during the etching process for the first element isolation insulator film 5a in the center of the first trench part 6a. The channel stop area 30 is formed with the second trench part 6b. For that reason, the channel profile of the channel stop area 30 in the semiconductor substrate 100 is stable without being affected by the depth of the first trench part 6a. FIGS. 12A, 12B, and 12C illustrate the channel stop area 30 for a nominal depth first trench part (12A), a shallower first trench than the nominal depth (12B), and a deeper first trench than the nominal depth (12C). The inter poly insulator film 22 or the poly silicon layer 23 and 24 are filled in the second trench part 6b, and an extra planarization is not necessary.

A junction leakage current in the embodiment can be reduced because the channel stop region 30 is located at a lower position than the conventional STI bottom which is the same level as the bottom of the first trench part 6a.

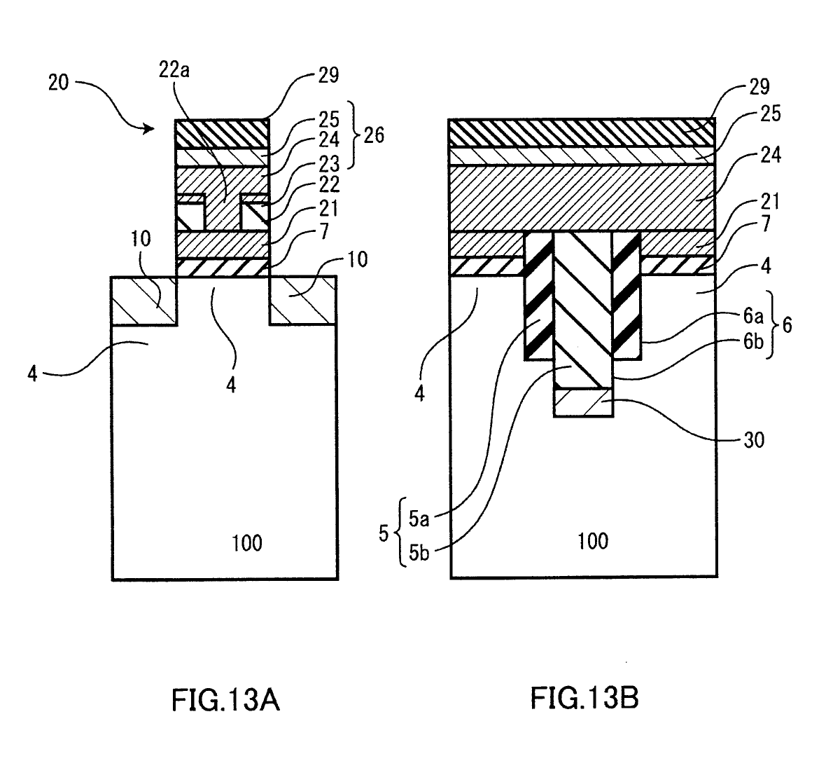

In FIG. 3B, the poly silicon layer 23 and 24 are filled in the divot of the second element isolation insulator film 5b at the second trench part 6b. However, in the case the width of the second trench part 6b is narrower than the twice of the thickness of the gate insulator film 22, as shown in FIG. 13B, there is no divot in the second element isolation insulator film 5b, and the second trench 6b is filled with the second element isolation insulator film alone.

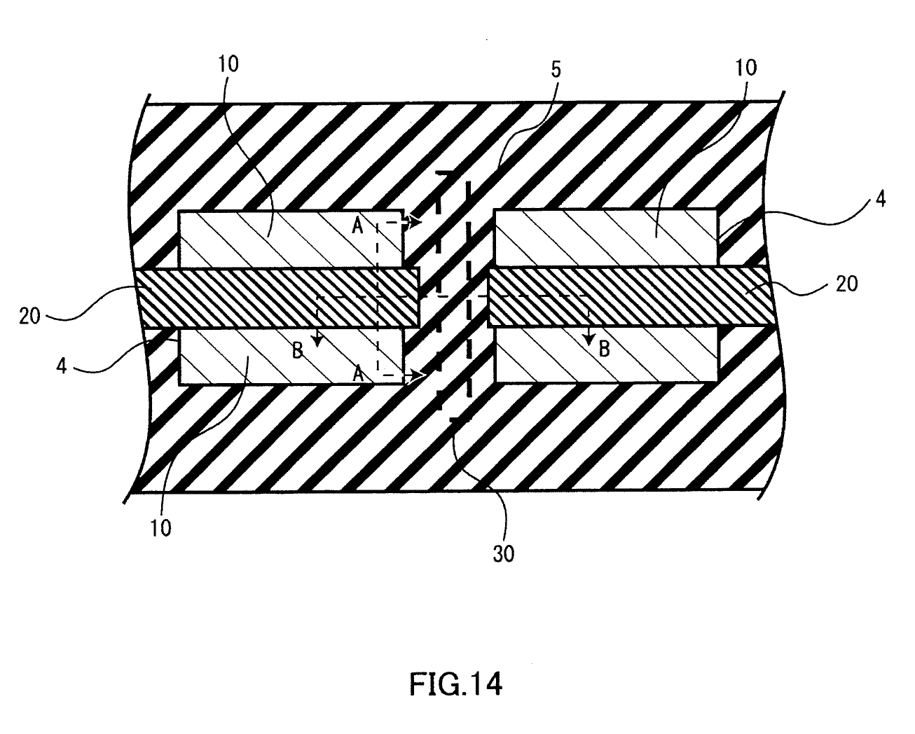

FIG. 14 shows a modified embodiment of the present invention. In this embodiment, the gate electrode 20 is not connected for a plurality of element areas 4. At a process step equivalent to FIG. 10 in the modified embodiment, the slit 22a of the inter poly insulator film 22 does not overlap on the divot 11 of the inter poly insulator film 22. Because of that, the divot 11 is filled during the etching process of the poly silicon layer 23.

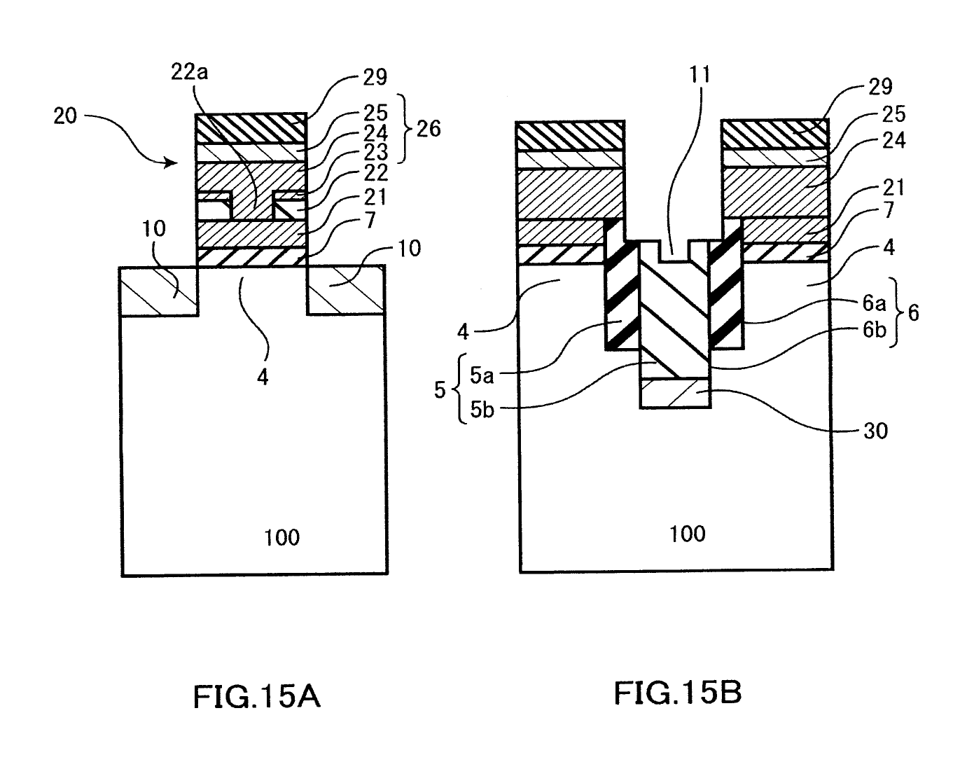

As shown in FIG. 15B, the divot 11 on the second element isolation insulator film 5b appears between the gate electrodes 20 after the formation of the gate electrodes 20. The height of the first and second element isolation insulator films 5a and 5b is reduced depending on the etching rate of the films, because the first and second element isolation films 5a and 5b is etched during the over etching process of the gate electrodes 20 at an area not covered by the gate electrode 20.

What is claimed is:

1. A semiconductor device comprising of:
a semiconductor substrate with a first impurity type;
a plurality of active areas formed in the semiconductor substrate;
an element isolation trench including a first trench part and a second trench part surrounding the plurality of active areas, the first trench part being extended from a surface of the semiconductor substrate to a depth direction, the second trench part being extended from the center of a bottom surface of the first trench part to the depth direction with a narrower width than the width of the first trench part in a width direction;
an element isolation insulator film filled in the element isolation trench;
a gate electrode formed on the plurality of active areas via a gate insulator film,
a plurality of diffusion layers with a second impurity type formed in a surface of the plurality of active areas, the plurality of diffusion layers being located on each side of the element isolation trench and separated each other on each side of the gate electrode; and
a channel stop region extended from the bottom surface of the second trench part to the depth direction in a predetermined depth with the first impurity type, the channel stop region having a higher impurity concentration than the impurity concentration of the semiconductor substrate.

2. The semiconductor device according to claim 1,
wherein the width of the channel stop region is equal with the width of the second trench part.

3. The semiconductor device according to claim 1,
wherein the element isolation insulator film includes a first element isolation insulator film and a second element isolation insulator film, and the second element isolation insulation film is filled in the second trench part and a region above the second trench part.

4. The semiconductor device according to claim 3,
wherein the gate electrode includes a lower gate electrode, an inter gate insulator film, and an upper gate electrode, and the inter gate insulator film is used to fill the second trench part and the region above the second trench part.

5. The semiconductor device according to claim 1, further comprising:
a divot on the element isolation insulator film, the divot being filled with a conductor.

6. The semiconductor device according to claim 2, further comprising:
a divot on the element isolation insulator film, the divot being filled with a conductor.

7. The semiconductor device according to claim 4, further comprising:
a divot on the element isolation insulator film, the divot being filled with a conductor.

8. The semiconductor device according to claim 1,
wherein the element isolation trench is used for the isolation of high voltage transistors of a NAND flash memory.

9. The semiconductor device according to claim 2,
wherein the element isolation trench is used for the isolation of high voltage transistors of a NAND flash memory.

10. The semiconductor device according to claim 4, wherein the element isolation trench is used for the isolation of high voltage transistors of a NAND flash memory.

11. A method of manufacturing a semiconductor device comprising:
forming a first trench part in a semiconductor substrate with a first impurity type;
filling the first trench part with a first element isolation insulator film;
planerizing a surface of the first element isolation insulator film;
forming a photo resist pattern on the surface of the first element isolation insulator film, the photo resist pattern having an opening on the center of the first element isolation insulator film;
etching the first element isolation insulator film to expose the semiconductor substrate at the bottom of the first trench part, using the photo resist pattern as a mask;
etching the exposed semiconductor substrate to form a second trench part, the second trench part having a narrower width than the width of the first trench part, and being extended from the bottom surface of the first trench part to a depth direction;
implanting ions of the first impurity type element to form a channel stop region using the photo resist pattern as a mask, the channel stop region being extended from the bottom of the second trench part to the depth direction in a predetermined depth with the first impurity type and having a higher impurity concentration than the semiconductor substrate;
filling a second element isolation insulator film in the second trench part;
forming a gate electrode on the surface of the semiconductor substrate via a gate insulator film; and
forming diffusion layers having a second impurity type opposite of the first impurity type in the surface of the semiconductor substrate, the diffusion layers being located on each side of the first trench part, and being separated each other on each side of the gate electrode.
